(19) United States
(12) Patent Application Publication
(10) Pub. No.: US 2007/0099371 A1
(43) Pub. Date: May 3, 2007

(54) CMOS image sensor and manufacturing method thereof

(76) Inventor: In Gyun Jeon, Gunpo-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/528,147

(22) Filed: Sep. 26, 2006

(30) Foreign Application Priority Data
Sep. 28, 2005 (KR) 10-2005-0090454

(51) Int. Cl. H01L 21/8238

(52) U.S. Cl. 438/199

(57) ABSTRACT

A CMOS image sensor and a method for manufacturing the same are provided. The method can include: forming a device isolation layer on a device isolation region of a semiconductor substrate; forming photodiodes on photodiode regions of the semiconductor substrate; forming a salicide metal layer and a barrier metal layer sequentially on the entire surface of the semiconductor layer; forming a light blocking layer between the photodiodes to block a light incident a photodiode from reaching an adjacent photodiode by selectively removing the salicide metal layer and the barrier metal layer that have not reacted during a silicide process; and forming a dielectric layer on the entire surface of the semiconductor substrate having the light blocking layer.

### RELATED APPLICATION

This application claims the benefit under 35 U.S.C. §119(e) of Korean Patent Application Number 10-2005-0090454 filed Sep. 28, 2005, which is incorporated herein by reference in its entirety.

### FIELD OF THE INVENTION

The present invention relates to a complementary metal oxide silicon (CMOS) image sensor, and more particularly, to a CMOS image sensor for preventing crosstalk by blocking light incident to adjacent pixels.

### BACKGROUND OF THE INVENTION

In general, an image sensor is a semiconductor device that transforms an optical image to electrical signals. An image sensor is generally classified as a charge coupled device (CCD) or a CMOS image sensor.

The CMOS image sensor is typically classified as a 3T type, a 4T type or a 5T type according to the number of transistors. The 3T type CMOS image sensor includes one photodiode and three transistors of a unit pixel, and the 4T type CMOS image sensor includes one photodiode and four transistors.

Hereinafter, the 3T CMOS image sensor will be described with reference to an equivalent circuit diagram and a layout thereof.

FIG. 1 is an equivalent circuit diagram of a 3T CMOS image sensor according to the related art.

As shown in FIG. 1, the unit pixel of the typical related art 3T CMOS image sensor includes one photodiode (PD) and three NMOS transistors T1, T2 and T3.

The photodiode includes a cathode connected to the drain of the first NMOS transistor T1 and the gate of the second NMOS transistor T2.

The sources of the first and second NMOS transistors T1 and T2 are connected to a power line that supplies a reference voltage, and the gate of the first NMOS transistor T1 is connected to a reset line that supplies a reset signal.

Also, the source of the third NMOS transistor T3 is connected to the drain of the second NMOS transistor, and the drain of the third NMOS transistor T3 is connected to a readout circuit (not shown) through a signal line. The gate of the third NMOS transistor T3 is connected to a column selection line that supplies a selection signal SLCT.

Herein, the first NMOS transistor T1 is a reset transistor Rx for resetting photocharge of the photodiode (PD) to the voltage level VR, and the second NMOS transistor T2 is a source flow transistor DX functioning as a source follower buffer amplifier. The third NMOS transistor T3 is a selection transistor Sx, which allows each pixel to be individually addressed.

Meanwhile, a predetermined portion of the reset transistor RX including the photodiode PD is a non salicide region, and the other portion of RX and the other transistors incorporate a salicide region.

FIG. 2 is a plan view of a CMOS image sensor according to the related art, and FIG. 3 is a cross-sectional view of the CMOS image sensor of FIG. 2 taken along the line IV-IV′.

As shown in FIGS. 2 and 3, a plurality of photodiodes 83 are formed on the semiconductor substrate 81 separated a predetermined distance from one another and isolated by a device isolation layer 82.

Also, a dielectric layer 84 is formed on the entire surface of the semiconductor substrate 81 having the photodiodes 83. Herein, the dielectric layer 84 is formed on the entire surface of the semiconductor substrate 81 after forming the salicide layer. The reference A denotes a photodiode boundary.

However, the CMOS image sensor according to the related art has a following problem.

That is, a crosstalk may be generated when light is leaked to an adjacent photodiode through the dielectric layer between photodiodes. The crosstalk degrades the image sensor characteristics.

Crosstalk is a phenomenon causing a data error by light incident to an undesired pixel.

### SUMMARY OF THE INVENTION

Accordingly, the present invention is directed to a CMOS image sensor and a method for manufacturing the same that addresses and/or substantially obviates one or more problems, limitations, and/or disadvantages of the related art.

An object of the present invention is to provide a CMOS image sensor for preventing crosstalk by blocking light incident to adjacent pixels.

Additional advantages, objects, and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

To achieve these objects and other advantages and in accordance with the purpose of the invention, as embodied and broadly described herein, there is provided a method of manufacturing a CMOS (complementary metal oxide silicon) image sensor including: forming a device isolation layer on a semiconductor substrate having photodiode regions and a device isolation region; forming photodiodes on the photodiode regions; forming a salicide metal layer and a barrier metal layer sequentially on the entire surface of the semiconductor substrate; selectively removing the metal layer and the barrier metal layer such that the metal layer and barrier metal layer remain on the device isolation layer to form a light blocking layer; and forming a dielectric layer on the entire surface of the semiconductor substrate having the light blocking layer.

In another aspect of the present invention, there is provided a CMOS (complementary metal oxide silicon) image sensor including: a semiconductor substrate including photodiode regions and device isolation regions; a device isolation layer formed on the device isolation regions of the semiconductor substrate; a photodiode formed on each of the photodiode regions of the semiconductor substrate; a light blocking layer formed on the device isolation layer; and a dielectric layer formed on the entire surface of the semiconductor substrate including the light blocking layer.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is an equivalent circuit diagram of a 3T CMOS image sensor according to the related art;

FIG. 2 is a plan view of a CMOS image sensor according to the related art;

FIG. 3 is a cross-sectional view of the CMOS image sensor of FIG. 2 taken along the line IV-IV′;

FIG. 4 is a plan view of a CMOS image sensor according to an embodiment of the present invention;

FIG. 5 is a cross-sectional view of the CMOS image sensor of FIG. 4 taken along the line V-V; and

FIGS. 6A through 6D are cross-sectional views of a CMOS image sensor for describing a method of manufacturing a CMOS image sensor according to an embodiment of the present invention.

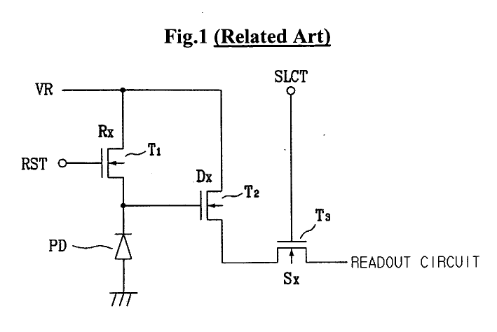

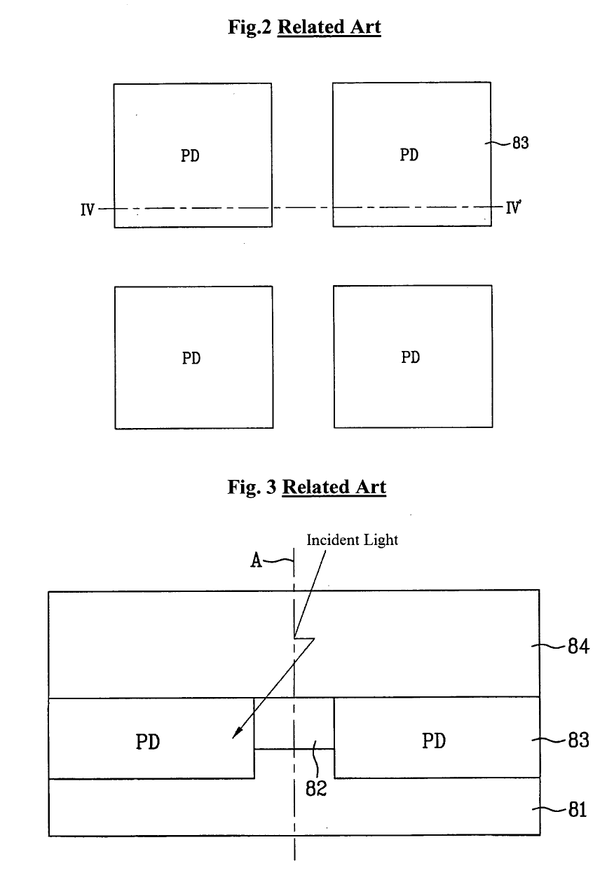

### DETAILED DESCRIPTION OF THE INVENTION

Reference will now be made in detail to the preferred embodiments of the present invention, examples of which are illustrated in the accompanying drawings. Wherever possible, the same reference numbers will be used throughout the drawings to refer to the same or like parts.

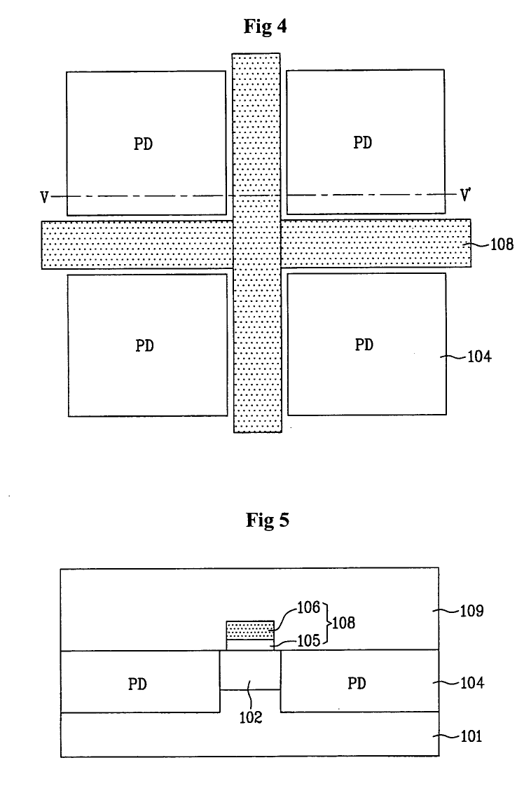

FIG. 4 is a plan view of a CMOS image sensor according to an embodiment of the present invention, and FIG. 5 is a cross-sectional view of the CMOS image sensor of FIG. 4 taken along the line V-V.

As shown in FIGS. 4 and 5, the CMOS image sensor according to an embodiment includes a plurality of photodiodes 104 formed on a semiconductor substrate 101 separated a predetermined distance from one another, a device isolation layer 102 formed between each of the photodiodes 104 in the semiconductor substrate 101, a light blocking layer 108 for blocking light incident one photodiode 104 from reaching an adjacent photodiode 104, and a dielectric layer 109 formed on the entire surface of the semiconductor substrate 101.

Herein, the light blocking layer 108 is formed of a metal layer 105. In a specific embodiment, the metal layer 105 can be made of one of Ti, Ta, Ni, or Co. In one embodiment, a barrier metal layer 106 can be formed on the metal layer 105 to a thickness of about 200 to 2000 Å.

The light blocking layer 108 can be formed on the device isolation layer 102 while not being formed on the active region of the semiconductor substrate 101 such that the light incident to one photodiode 104 can be blocked from reaching an adjacent photodiode 104 through the device isolation layer 102.

The light blocking layer 108 can be formed on the device isolation layer 102 within a corresponding pixel so as to block the light from reaching an adjacent photodiode 104 through the device isolation layer 102.

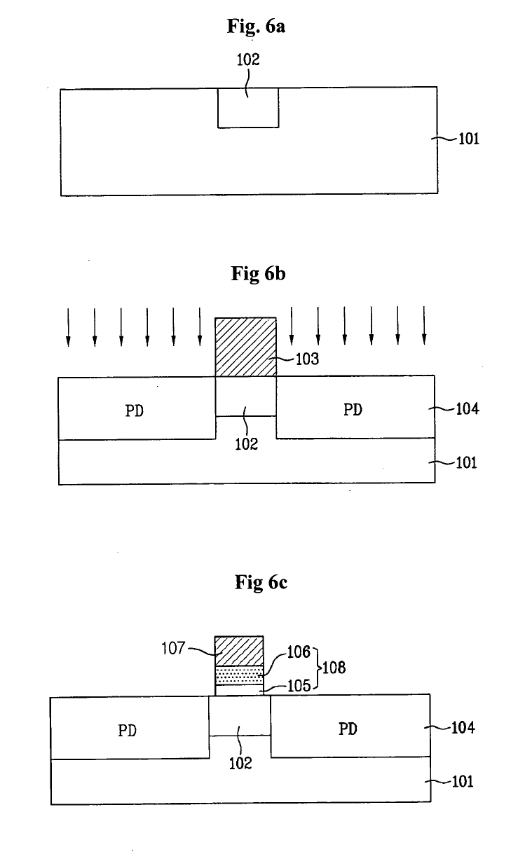

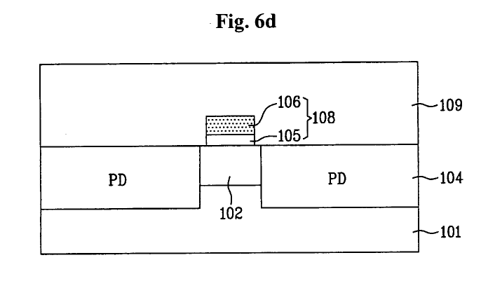

FIGS. 6A through 6D are cross-sectional views of a CMOS image sensor for describing a method of manufacturing a CMOS image sensor according to an embodiment of the present invention.

That is, a light blocking layer can be formed using a salicide layer when a salicide process is performed after forming transistors.

As shown in FIG. 6A, a device isolation layer 102 can be formed at the semiconductor substrate 101 to isolate the devices.

Although it is not shown in the accompanying drawings, the device isolation layer 102 can be formed as follows.

A pad oxide layer, a pad nitride layer and a Tetra Ethyl Ortho Silicate (TEOS) oxide layer can be sequentially formed on the semiconductor substrate. Then a photoresist layer can be formed on the TEOS oxide layer.

The photoresist layer can be patterned by exposing and developing processes using a mask that defines an active region and a device isolation region.

Then, the pad oxide layer, the pad nitride layer and the TEOS oxide layer can be selectively removed from the device isolation regions using the patterned photoresist layer as a mask.

A trench can be formed by etching the exposed substrate in the device isolation region to a predetermined depth using the patterned pad oxide layer, pad nitride layer and TEOS oxide layer as a mask. Then, the photoresist layer can be removed.

After removing the photoresist layer, a thin sacrificial oxide layer can be formed on the entire surface of the trench, and an O₃ TEOS layer can be formed to fill the trench. Herein, the sacrifice oxide layer can also be formed on the inner wall of the trench. In a specific embodiment, the O₃ TEOS layer can be formed at a temperature higher than about 1000° C.

Then, the O₃ TEOS layer can be removed by performing chemical mechanical polishing (CMP) on the entire surface of the semiconductor substrate 101 in order to leave the trench regions. That is, the device isolation layer 102 is formed inside the trench. Afterward, the pad oxide layer, the pad nitride layer and the TEOS oxide layer can be removed.

As shown in FIG. 6B, a first photoresist layer 103 can be formed on the entire surface of the semiconductor substrate 101, and selectively patterned by exposing and developing processes so as to define a photodiode region.

Then, a photodiode 104 can be formed by implanting impurity ions at low concentration into the photodiode region of the semiconductor substrate 101 using the patterned first photoresist layer 103 as a mask.

Referring to FIG. 6C, a salicide layer (not shown) can be formed on a salicide region (not shown) of the semiconductor substrate 101 by removing the first photoresist layer 103, depositing a salicide metal layer 105 on the entire surface of the semiconductor substrate 101, and performing a first annealing process.

In one embodiment, the metal layer 105 can be made of, for example, Ti, Ta, Ni, or Co. A barrier metal layer 106 can be formed on the metal layer 105. In an embodiment, the barrier metal layer 106 may be formed of TiN or TaN.

In a specific embodiment, the barrier metal layer 106 can be formed to a thickness of about 200 to 2000 Å.

Then, a second photoresist layer 107 can be formed on the entire surface of the semiconductor layer 101 having the unreacted metal layer 105. Then, the second photoresist layer 107 can be selectively patterned to leave the second photoresist layer 107 on the device isolation layer 102 between the photodiodes 104.

A light blocking layer 108 can be formed by selectively removing the unreacted metal layer 105 and barrier metal layer 106 using the patterned second photoresist layer 107 as a mask. The light blocking layer 108 blocks an incident light to a predetermined pixel to be leaked to adjacent photodiodes 104

As shown in FIG. 6D, the salicide layer can be stabilized by removing the second photoresist layer 107 and performing a second annealing process on the semiconductor substrate 101.

Then, a dielectric layer 109 can be formed on the entire surface of the semiconductor layer 101 having the light blocking layer 108.

As described above, the method of manufacturing a CMOS image sensor according to the present invention has a following advantage.

The crosstalk can be suppressed by blocking a light incident a predetermined pixel from reaching adjacent photodiodes by leaving metal material between the photodiodes through the salicide process. Therefore, the characteristics of the CMOS image sensor are improved.

It will be apparent to those skilled in the art that various modifications and variations can be made in the present invention. Thus, it is intended that the present invention covers the modifications and variations of this invention provided they come within the scope of the appended claims and their equivalents.

I claim:

1. A method of manufacturing a CMOS (complementary metal oxide silicon) image sensor comprising:
forming a device isolation layer on a semiconductor substrate having photodiode regions and a device isolation region;
forming photodiodes on the photodiode regions of the semiconductor substrate;
forming a salicide metal layer and a barrier metal layer sequentially on the entire surface of the semiconductor layer;
forming a light blocking layer between the photodiodes by selectively removing the salicide metal layer and the barrier metal layer that are unreacted; and
forming a dielectric layer on the entire surface of the semiconductor substrate having the light blocking layer.

2. The method according to claim 1, wherein the salicide metal layer is Ti, Ta, Ni, or Co.

3. The method according to claim 1, wherein the barrier metal layer is TiN or TaN and formed to a thickness of about 200 to 2000 Å.

4. The method according to claim 1, wherein the light blocking layer is formed on the device isolation region and not on an active region.

5. The method according to claim 1, wherein the light blocking layer is formed on the device isolation layer in a pixel.

6. The method according to claim 1, wherein the light blocking layer is formed on a device isolation layer between adjacent photodiodes.

7. A CMOS (complementary metal oxide silicon) image sensor comprising:
a semiconductor substrate including photodiode regions and device isolation regions;
a device isolation layer formed on the device isolation region of the semiconductor substrate;
a photodiode formed on each of the photodiode regions of the semiconductor substrate;
a light blocking layer formed on the device isolation layer; and
a dielectric layer formed on the entire surface of the semiconductor substrate including the light blocking layer.

8. The CMOS image sensor according to claim 7, wherein the light blocking layer includes a salicide metal layer and a barrier metal layer formed on the metal layer.

9. The CMOS image sensor according to claim 8, wherein the metal layer is Ti, Ta, Ni, or Co.

10. The CMOS image sensor according to claim 8, wherein the barrier metal layer is TiN or TaN and formed to a thickness of about 200 to 2000 Å.

11. The CMOS image sensor according to claim 8, wherein the light blocking layer is formed on the device isolation layer and not on an active region.

12. The CMOS image sensor according to claim 8, wherein the light blocking layer is formed on the device isolation layer in a pixel.

13. The CMOS image sensor according to claim 8, wherein the light blocking layer is formed on the device isolation layer between adjacent photodiodes.
